(19) United States
(12) Patent Application Publication
(10) Pub. No.: US 2007/0104960 A1
(43) Pub. Date: May 10, 2007

(54) Liquid epoxy resin composition

(75) Inventors: Masatoshi Asano, Annaka-shi (JP); Kaoru Katoh, Annaka-shi (JP); Kazuaki Sumita, Annaka-shi (JP)

Correspondence Address: BIRCH STEWART KOLASCH & BIRCH, PO BOX 747, FALLS CHURCH, VA, 22040-0747, US

(73) Assignee: Shin-Etsu Chemical Co., Ltd., Tokyo (JP)

(21) Appl. No.: 11/591,473

(22) Filed: Nov. 2, 2006

(30) Foreign Application Priority Data
Nov. 2, 2005 (JP) 2005-319184
Apr. 21, 2006 (JP) 2006-118452
Oct. 23, 2006 (JP) 2006-287811

(51) Int. Cl. B32B 27/38; H01L 21/56; C08L 63/00; B32B 37/00

(52) U.S. Cl. 428/413; 438/127; 523/428; 525/476

(57) ABSTRACT

A liquid epoxy resin composition comprising (A) a liquid epoxy resin (B) an amine curing agent and (C) an inorganic filler in an amount of from 50 to 900 parts by weight per 100 parts by weight of the component (A), wherein the component (B) is contained in such an amount that a molar ratio of epoxy groups of the component (A) to amino groups of the component (B), ranges from 0.6 to less than 1.0, provided that, if the component (B) includes an amine curing agent which is solid in the composition at a temperature of from room temperature to 150° C., a content of such an amine is 30 mol % or less, based on the component (B).

This application claims benefit of Japanese Patent application No. 2005-319184 filed on Nov. 2, 2005, Japanese Patent application No. 2006-118452, filed on Apr. 21, 2006 and Japanese Patent application No. 2006-287811, filed on Oct. 23, 2006, the contents of which are hereby incorporated by reference.

### FIELD OF THE INVENTION

The present invention relates to a liquid epoxy resin composition for encapsulating a semiconductor device. The present invention also relates to a semiconductor device encapsulated with the composition.

The present composition is easy to handle and allows simplification of semiconductor device production process.

### BACKGROUND OF THE INVENTION

As semiconductor devices are getting smaller, thinner and lighter, more and more semiconductor chips are integrated in a device. The semiconductor chip is commonly mounted on a circuit board by flip-chip attach method. A typical flip-chip attach method is the controlled collapse chip connection (C4) process in which electrodes of the semiconductor chip is directly soldered with solder bumps or lands on a circuit board. After the soldering, the gap between the chip and the circuit board is sealed or encapsulated with an epoxy resin.

In conventional C4 process, the resin encapsulation is performed by capillary flow method. However, the process has drawback of low productivity due to many steps involved: 1) treatment of solder with flux, 2) soldering, 3) cleaning of the flux, 4) injection of an encapsulation resin by capillary flow method, and 5) curing of the resin. As pads are getting finer with narrower pitch, cleaning of the flux is getting more and more difficult. Residual flux on the circuit board respells an encapsulation resin, and ionic impurities in residual flux degrade reliability of a device package.

To solve these problems, U.S. Pat. No. 5,128,746 discloses a non-flow method in which soldering and resin encapsulation is performed in a single step by applying an encapsulation resin comprising flux component to a circuit board and then placing a semiconductor chip having solder electrodes on the applied resin.

For use in the non-flow method, various compositions comprising a curing agent performing as flux as well are proposed, for example, a phenolic resin as described in Japanese Patent Application Laid-Open No. 2002-232123, a phenolic carboxylic acid as described in Japanese Patent Application Laid-Open No. 2003-128874, an acid anhydride as described in Japanese Patent Application Laid-Open No. 2001-329048 and 2003-160639, a carboxylic acid as described in Japanese Patent Application Laid-Open No. 2002-293883 and an aromatic carboxylic acid hydrazide as described in Japanese Patent Application Laid-Open No. 2004-303874.

A composition comprising a flux component besides a curing agent are also known. For example, a composition comprising a carboxylic acid or a block carboxylic acid as flux component in addition to a phenolic or acid anhydride curing agent are known from Japanese Patent Application Laid-Open No. 2002-190497, 2003-82064, and 2001-223227.

### SUMMARY OF THE INVENTION

Most of the curing agents in the aforesaid compositions are phenolic or acid anhydrides curing agents. Comparing these curing agents, an amine curing agent generally can provide a cured product with stronger adhesion to a substrate and less exfoliation from the substrate or a semiconductor chip. In Japanese Patent Application Laid-Open No. 2002-293883, an amine adduct curing agent is examined but it is concluded that the amine adduct has no flux capability.

An object of the present invention is to provide a composition which comprises an amine curing agent and is advantageously used in the non-flow method.

The inventors have found that an epoxy resin composition comprising specific amount of an amine curing agent, or a specific monoamine compound in addition to the amine curing agent is suitably used as an encapsulation resin in the non-flow method.

Thus, the present invention is a liquid epoxy resin composition comprising

(A) a liquid epoxy resin

(B) an amine curing agent and

(C) an inorganic filler in an amount of from 50 to 900 parts by weight per 100 parts by weight of the component (A), wherein

the component (B) is contained in such an amount that a molar ratio of epoxy groups of the component (A) to amino groups of the component (B), ranges from 0.6 to less than 1.0, provided that, if the component (B) includes an amine curing agent which is solid in the composition at a temperature of from room temperature to 150° C., a content of such an amine is 30 mol % or less, based on the component (B).

Another aspect of the present invention is a liquid epoxy resin composition comprising

(A) a liquid epoxy resin

(B) an amine curing agent and

(C) an inorganic filler in an amount of from 50 to 900 parts by weight per 100 parts by weight of the component (A), wherein

the component (B) is contained in such an amount that a molar ratio of epoxy groups of the component (A) to amino groups of the component (B) ranges from 0.8 to less than 1.1, and the composition further comprises

(D) a monoamine compound having a melting point of 200° C. or lower and a boiling point of 200° C. or higher in an amount of from 0.1 to 20 parts by weight per total 100 parts by weight of the components (A) and (B).

The present invention also provides a composition for encapsulating a flip-chip type semiconductor comprising the aforesaid present composition, and a flip-chip type semiconductor device comprising a cured product of the composition.

By utilizing the amine curing agent's or the monoamine's capability as flux in addition to strong adhesion strength attained by the amine curing agent, the present liquid epoxy composition is suitable for use in the non-flow method for manufacturing flip-chip type semiconductor devices.

### BRIEF DESCRIPTION OF THE DRAWING

FIG. 1 is a cross sectional view of a flip-chip type semiconductor device of the present invention.

### PREFERRED EMBODIMENTS OF THE INVENTION

Each component of the present composition is explained.

(A) Liquid Epoxy Resin

In the present invention, the liquid epoxy resin has at least two epoxy groups per molecule and is liquid including viscous liquid at room temperature. As the liquid epoxy resin, known epoxy resins can be used. Examples of the liquid epoxy resin include bisphenol A type epoxy resins, bisphenol AD type epoxy resins, bisphenol F type epoxy resins, naphthalene type epoxy resins, phenol novolac type epoxy resins, biphenyl type epoxy resins, glycidylamine epoxy resins, cycloaliphatic epoxy resins, dicyclopentadiene type epoxy resins, and a mixture of two or more of these. Among these, bisphenol A type epoxy resins, bisphenol F type epoxy resins, bisphenol AD type epoxy resins, and naphthalene type epoxy resins are preferred because of good resistance to heat and moisture.

Preferably, a total content of chlorine, originating from epichlorohydrin used to prepare the epoxy resin, of the epoxy resin is not more than 1500 ppm, more preferably not more than 1000 ppm. Further, a content of chlorine extractable with deionized water at 100° C. for 20 hours of the epoxy resin is not more than 10 ppm.

(B) Amine Curing Agent

Examples of amine curing agents include 3,3′-diethyl-4,4′-diaminodiphenymethane, 3,3′,5,5′-tetramethyl-4,4′-diaminodiphenylmethane, 2,4-diaminotoluene, 1,4-phenylenediamine, 1,3-phenylenediamine, diethyltoluenediamine, 3,4-diaminodiphenyl ether, 3,3-diamiodiphenylmethane, 3,4-diamiodiphenylmethane, 4,4-diamiodiphenylmethane, 3,3′-diaminobenzidine, o-tolidine, 3,3′-dimethyl-4,4′-diaminodiphenylmethane, 3,3′-diethyl-4,4′-diaminodiphenylmethane, 2,4-diaminotoluene, 2,6-diaminotorluene, 1,2-phenylenediamine, 1,4-phenylenediamine, 1,3-phenylenediamine, 1,8-diaminonaphthalene, and a mixture thereof.

Examples of aliphatic amine include aliphatic linear amines such as N,N-bis(3-aminopropyl)ethylenediamine, 3,3-diaminodipropylamine, 1,8-diaminooctane, 1,10-diaminodecane, 3,3-diaminodipropylamine, diethylenetriamine, triethylenetetramine, and tetraethylenepentamine; and aliphatic cyclic amines such as 1,4-bis(3-aminopropyl)piperazine, N-(2-aminoethyl)peperazine, N-(2-aminoethyl)morpholine, N-aminoethylpiperazine, and isophoronediamine. Polyamideamines are amines produced by condensation reaction of dimer acids with polyamines whose examples include adipic acid dihydrazide and 7,11-octadecadiene-1,18-dicarbohydrazide. Examples of imidazol curing agents include 2-methylimidazol, 2-ethyl-4-methylimidazol, and 1,3-bis(hydrazinocarbonoethyl-5-isopropyl hydantoin. Examples of guanidine curing agents include 1,3-diphenylguanidine, 1,3-o-triguanidine.

Among the aforesaid amines, 1,2-phenylenediamine, 1,3-phenylenediamine, 1,4-phenylenediamine, 1,3-bis(hydrazinocarbonoethyl-5-isopropyl hydantoin and 7,11-octadecadiene-1,18-dicarbohydrazide are preferred.

The amine curing agent (B) is contained in such an amount that a molar ratio of epoxy groups of the epoxy resin (A) to active hydrogen atoms of the amine curing agent (B), [a molar amount of epoxy groups of the epoxy resin (A)/a molar amount of active hydrogen atoms of the amine curing agent (B)], is less than 1.0, preferably less than 0.9, more preferably less than 0.8, and not less than 0.6, more preferably not less than 0.7. Within the aforesaid range, the amine curing agent (B) functions as flux component in addition to as curing agent. If the ratio is less than the aforesaid lower limit, more amino groups or phenolic hydroxyl groups remain unreacted, and a cured product may have a lower glass transition temperature and lower adhesion strength. If the ratio exceeds the aforesaid upper limit, sufficient effect as flux may not be attained, and a cured product is so brittle that it may crack during reflow process.

When the component (B) includes an amine curing agent which is solid in the composition at a temperature of from room temperature to 150° C., such an amine curing agent is contained in an amount of 30 mol % or less, preferably 20 mol % or less, based on the component (B). Such an solid amine curing agent does not dissolve or swell in the liquid epoxy resin (A) or other liquid amine curing agent, if the component (B) includes a liquid amine curing agent. Among aforesaid examples of the amine curing agent, adipic acid dihydrazide is an example of the solid curing agent. If more than aforesaid amount of the solid amine curing agent is contained, surface of a curing product may not be smooth.

An amine curing agent, which is solid at room temperature but can be melt mixed with the epoxy resin or a liquid amine, is preferably melt mixed at a temperature of from 70 to 150° C. for 1 to 2 hours prior to mixing with other components. At a temperature below 70° C. or a time shorter than 1 hr, the solid amine may not be sufficiently mixed. Above 150° C. or a time longer than 2 hours, a reaction with the epoxy rein may occur, leading to increase in viscosity of a composition.

Preferably, the amine curing agent has a boiling point of 200° C. or higher, preferably 240° C. or higher. Preferably, the amine curing agent has an amine equivalent, i.e., an active hydrogen equivalent, of from 20 to 100, more preferably from 25 to 50. If the amine equivalent is lower than the aforesaid lower limit, a cured product may be so hard that it has lower adhesion strength or cracks.

When component (E) silicon-modified epoxy resin, which is described later, is contained in the composition, a molar amount of total epoxy groups of components (A) and (E), in place of molar amount of epoxy group of component (A), falls within the aforesaid range. If the component (E) has phenolic hydroxyl groups, a molar amount of active hydrogen amount of components (B) and (E), in place of a molar amount of active hydrogen of the amine curing agent (B), falls within the aforesaid range.

(D) Monoamine Compound

As a flux component, a monoamine can be used. The monoamine compound has a melting point of 200° C. or lower, preferably 150° C. or lower. The monoamine has a boiling point of 200° C. or higher, preferably 240° C. or higher. A monoamine having a melting point higher than 200° C. tends to have poor miscibility in the composition, resulting in insufficient soldering effect. A monoamine having a boiling point lower than 200° C. tends to vaporize to form voids in a cured product, and no function as soldering flux may be attained.

Examples of the monoamine include aniline derivatives such as o-,m-,p-anisidine and diethylaniline; and benzylamine derivatives such as 2,4-dimethylbenzylamine, 3-aminobenzylamine, and 4-aminobenzylamine. Preferably, p-anisidine or 2,6-diethylaniline is used.

Preferably, the monoamine has an active hydrogen equivalent, hereinafter referred to as amine equivalent, of from 20 to 100, preferably from 25 to 50. A monoamine with an amine equivalent above the aforesaid upper limit may not sufficiently function as flux.

When the composition comprises the monoamine compound (D), the amine curing agent (B) is contained in such an amount that the ratio of a molar amount of epoxy groups of component (A) to a molar amount of amino groups of component (B), [a molar amount of epoxy groups of component (A)/a molar amount of amino groups of component (B)], ranges from 0.8 to 1.1, preferably from 0.9 to 1.0.

Component (D) is contained in the composition in an amount of from 0.1 to 20 parts by weight, preferably from 1 to 10 parts by weight, per total 100 parts by weight of the components (A) and (B). If it is contained in an amount less than the aforesaid lower limit, sufficient flux effect may not be attained. If it is contained more than the aforesaid upper limit, a cured product may have too low glass transition temperature or adhesion strength.

When the monoamine compound is solid at room temperature, it is preferably mixed with the liquid epoxy resin or a liquid amine curing agent at a temperature of from 70 to 150° C. for 1 to 2 hours prior to mixing other components.

(C) Inorganic Filler

By containing the inorganic fillers, a cured product of the composition has a reduced thermal expansion coefficient. Any known filler can be used, for example, fused silica, crystalline silica, alumina, titanium dioxide, silica/titania, boron nitride, aluminum nitride, silicon nitride, magnesia, magnesium silicate, aluminum and a mixture of two or more of these. Preferably, spherical fused silica is used because of a lower viscosity of a composition containing the fused silica.

The inorganic filler is preferably pretreated with a coupling agent such as silane coupling agent or titanate coupling agent to increase affinity to the resins. Preferably, silane coupling agents are used whose examples include epoxy silanes such as γ-glycidoxypropyltrimethoxysilane, γ-glycidoxypropylmethyldiethoxysilane, β-(3,4-dpoxycyclohexyl)ethyltrimethoxysilane; aminosilanes such as N-β(aminoethyl)-γ-aminopropyltrimethoxysilane, γ-aminopropyltriethoxysilane, N-phenyl-γ-aminopropyltrimethoxysilane; and mercaptosilanes such as γ-mercaptosilane.

The inorganic filler is contained in the composition in an amount of from 50 to 900 parts by weight, preferably from 100 to 500 parts by weight per 100 parts by weight of the epoxy resin. A composition containing the filler in an amount less than the aforesaid lower limit gives a cured product which may have larger expansion coefficient which may crack in a heat cycle test. A composition containing the filler in an amount above the aforesaid upper limit may has higher viscosity which tends to form voids in a cured product. Further, the filler may inhibit solder connection.

The present composition may contain the following components in an amount not to adversely affect the composition.

(E) Silicone-Modified Epoxy Resin

The present composition may contain a silicone-modified epoxy resin as a flexibilizer to make a cured product flexible. Examples of the flexibilizer include silicone resins in the form of powder, rubber, and oil, thermoplastic resins such as liquid polybutadiene rubber and acrylic core-shell resin. Preferably, the silicone-modified epoxy resin is used. Particularly, a addition reaction product of an epoxy resin or a phenolic resin with an organopolysiloxane. The epoxy resin or a phenolic resin has an alkenyl group and is represented by the following formulas (1), (2), (3) or (4). 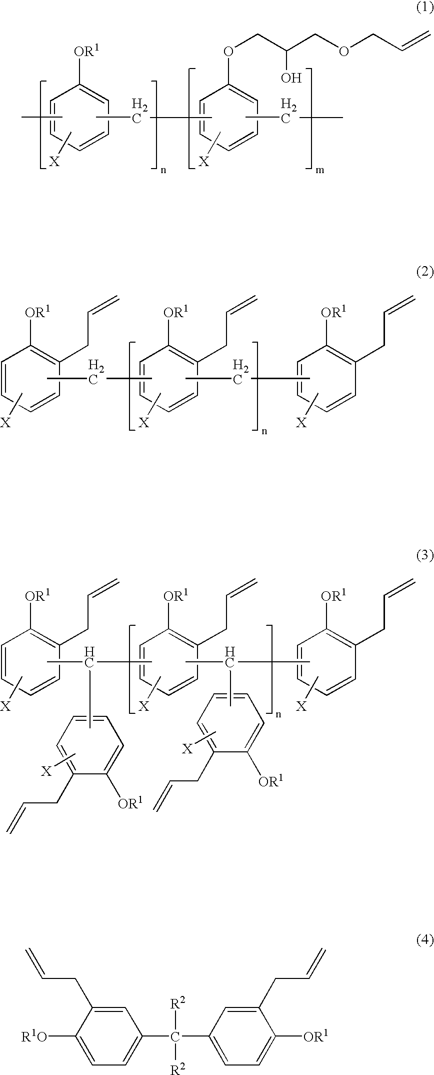
wherein R¹ is a hydrogen atom or the group shown below, 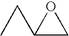
R² is a hydrogen atom or a methyl group, X is a hydrogen atom or a monovalent hydrocarbon group having 1 to 6 carbon atoms, n is an integer of from 0 to 50, preferably from 1 to 20, and m is an integer of from 1 to 5, preferably 1, and the organopolysiloxane is represented by the following average compositional formula
HₐR³_{b}SiO_{(4-a-b)/2} (5)
wherein R³ is a substituted or unsubstituted monovalent hydrocarbon group, a is a number of from 0.01 to 0.1, b is a number of from 1.8 to 2.2, with a sum of a and b ranging from 1.81 to 2.3, which organopolysiloxane has 10 to 400 silicon atoms and 1 to 5 SiH bonds per molecule.

Preferred R³ is a monovalent hydrocarbon group having 1 to 10, particularly, 1 to 8 carbon atoms. Examples of such a group include alkyl groups such as methyl, ethyl, propyl, isopropyl, butyl, isobutyl, tert-butyl, hexyl, octyl, and decyl groups; alkenyl groups such as vinyl, allyl, propenyl, and hexenyl groups; aryl groups such as phenyl, xylyl, and tolyl groups; aralkyl groups such as benzyl, phenylethyl, and phenylpropyl groups, and partially or fully halogen substituted groups thereof such as fluoromethyl, bromoethyl, and trifluoropropyl groups.

A preferred silicone-modified epoxy resin is represented by the following formula (6).

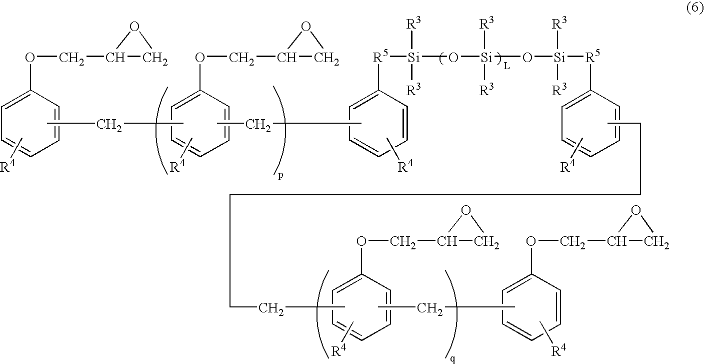

In the above formula (6), R⁴ is a hydrogen atom or a monovalent hydrocarbon group having 1 to 6 carbon atoms, and R⁵ is a divalent group represented by the formula, —CH₂CH₂CH₂—, —OCH₂—CH(OH)—CH₂—O—CH₂CH₂CH₂— or —O—CH₂CH₂CH₂—. L is an integer of from 8 to 398, preferably from 18 to 198 and p is an integer of from 1 to 10, and q is an integer of from 1 to 10.

Examples of R⁴ include alkyl groups such as methyl, ethyl, propyl, isopropyl, butyl, isobutyl, tert-butyl, hexyl, octyl, and decyl groups; cycloalkyl groups such as cyclopentyl and cyclohexyl groups; alkenyl groups such as vinyl, allyl, propenyl, and hexenyl groups; and aryl groups such as phenyl group, among which methyl group is preferred. R^{4′} may be different from each other.

In the formula (6), p and q are integers of from 1 to 10, preferably from 1 to 5. If p and/or q is larger than 10, a cured product may be too hard, resulting in cracking, weak adhesion or low reliability of a device package.

In the formula (6), L is an integer of from 8 to 398, preferably from 18 to 198. A silicone-modified resin with L being less than 8 is not sufficiently flexible due to too little portion of polysiloxane moieties in a molecule. A resin with L being larger than 398 may be difficult to disperse in a composition, and a composition obtained has unstable quality.

Component (E) is incorporated in the composition in an amount of 20 parts by weight or less, particularly from 2 to 15 parts by weight, per 100 parts by weight of component (A) to attain sufficient flexibilizing effect.

Optional Additives

The present composition may contain optional additives such as cure promoters, surfactants, antifoaming agents, leveling agents, ion trap agents, pigments such as carbon black, and dye stuffs, in an amount not to adversely affect the composition.

The present composition can be prepared by mixing the liquid epoxy resin (A), the amine curing agent (B), nitrogen compound (C), inorganic filler (D), and optional additives in a batch process or a serial process. Any mixing means can be used such as an automatic mortar equipped with a stirrer and a heater, a three-roller mill, a ball mill, and a planetary mixer. These mixing means may be used in combination.

The present liquid epoxy composition has a viscosity of 1000 Pa·s or smaller, particularly of 500 Pa·s or smaller, at 25° C. The composition is preferably cured at a temperature of from 100 to 120° C. for about 0.5 hour and then at a temperature of from 150 to 175° C. for about 0.5 to 4 hours. The first heating step ensures to obtain a cured product without voids. If a period of time of the second heating step at 150 to 175° C. is shorter than 0.5 hour, cured product may not have satisfactory properties.

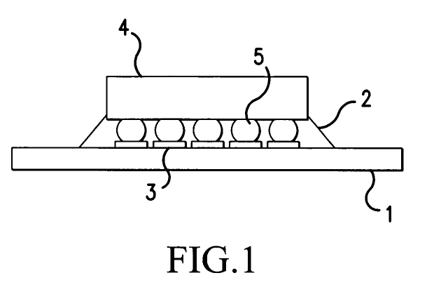

FIG. 1 shows an example of a flip-chip type semiconductor package. In the package, a semiconductor chip 4 is mounted on a surface of an organic substrate having a circuit pattern via a plurality of solder bumps 5. The gap between the organic substrate 1 and the semiconductor chip 4 is filled or encapsulated with an underfill 2. The present composition is particularly useful as an underfill adhesive.

When the present liquid epoxy resin composition is used as an underfill, the composition forms a cured product having a coefficient of thermal expansion preferably of from 20 to 40 ppm/° C. at a temperature not higher than its glass transition temperature.

### EXAMPLES

The present invention will be explained with reference to the examples but not limited thereto. In the following description, % means wt % and parts means parts by weight, unless otherwise specified.

The following substances are used.

(A) Liquid Epoxy Resin

Epoxy resin (a): Bisphenol F type epoxy resin having an epoxy equivalent of 170, RE303S-L, ex Nippon Kayaku Co., Ltd. Epoxy resin (b): Trifunctional epoxy resin of the following formula (7) having an epoxy equivalent of 101, Epikote 630H, Japan Epoxy Resin Co.

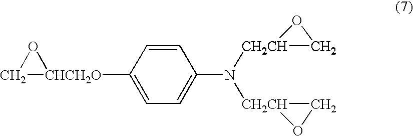

(B) Amine Curing Agent

1. 3,3′-diethyl-4,4′-diaminodiphenylmethane having an amine equivalent of 63.5, Kayahard A-A, Nippon Kayaku Co., Ltd

2. diethyltoluenediamine, Albamer & Co Ltd.

3. 7,11-octadecadiene-1,18-dicarbohydrazide, Amicure UDH, ex Ajinomoto Finetechno Co.

4. 1,3-bis(hydrazinocarbonoethyl-5-isopropyl hydantoin, Amicure VDH, ex Ajinomoto Finetechno Co.

5. 4,4-diaminodiphenylmethane

6. 1,4-phenylenediamine

7. 3,3-diaminodipropylamine

(C) Spherical Silica Having an Average Particle Diameter of 2 μm and a Maximum Particle Diameter of 10 μm, ex Tatsumori Ltd.

(D) Monoamine Compound

1. p-anisidine

2. 2,6-diethylaniline

(E) Silicone-Modified Epoxy Resin

An addition polymerization product of the compound of the following formula (8) with the compound of the formula (9), having a weight average molecular weight of 3800 and an epoxy equivalent of 291 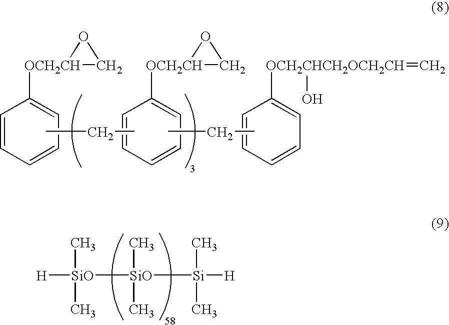
Other Additives

Carbon black: Denka black, ex Denki Kagaku Kogyo Kabushiki Kaisya Silane coupling agent: γ-glycidoxypropyltrimethoxysilane, KBM403, ex Shin-Etsu Chemical Co. Ltd.

### Compounds Used in Referential Examples

1. octadecylamine

2. aniline

3. 1,6-diaminopyrene

4. 2-aminoethanol

### Example 1

Using a planetary mixer, 31.8 parts by weight of the epoxy resin (a), 31.8 parts by weight of the epoxy resin (b), 45.5 parts by weight of the amine curing agent, 3,3′-diethyl-4,4′-diaminodiphenylmethane, 100 parts by weight of the spherical silica, 4 parts by weight of the silicone-modified epoxy resin, 1 part by weight of the silane coupling agent, and 1 part by weight of the carbon black were thoroughly mixed and then kneaded with a three-roller mill to well disperse solid substances. The mixture obtained was deaerated under vacuum. The liquid epoxy resin composition obtained had a molar ratio, [epoxy groups/amino groups], of 0.70.

### Example 2

A composition was prepared in the same manner as in Example 1 except that 35.4 parts by weight of 3,3′-diethyl-4,4′-diaminodiphenylmethane was used. The composition obtained had a molar ratio, [epoxy groups/amino groups], of 0.90.

### Example 3

A composition was prepared in the same manner as in Example 1 except that 39.8 parts by weight of 3,3′-diethyl-4,4′-diaminodiphenylmethane was used. The composition obtained had a molar ratio, [epoxy groups/amino groups], of 0.80.

### Example 4

A composition was prepared in the same manner as in Example 1 except that 26.3 parts by weight of diethyltoluenediamine was used in place of 3,3′-diethyl-4,4′-diaminodiphenylmethane. The composition obtained had a molar ratio, [epoxy groups/amino groups], of 0.85.

### Example 5

A composition was prepared in the same manner as in Example 1 except that 5 parts by weight of 7,11-octadecadiene-1,18-dicarbohydrazide in addition to 33 parts by weight of 3,3′-diethyl-4,4′-diaminodiphenylmethane was used. The composition obtained had a molar ratio, [epoxy groups/amino groups], of 0.87.

### Example 6

A composition was prepared in the same manner as in Example 1 except that 5 parts by weight of 1,3-bis(hydrazinocarbonoethyl-5-isopropyl hydantoin in addition to 33 parts by weight of 3,3′-diethyl-4,4′-diaminodiphenylmethane was used. The composition obtained had a molar ratio, [epoxy groups/amino groups], of 0.86.

### Example 7

A composition was prepared in the same manner as in Example 1 except that 5 parts by weight of 4,4-diaminodiphenylmethane in addition to 33 parts by weight of 3,3′-diethyl-4,4′-diaminodiphenylmethane was used. The composition obtained had a molar ratio, [epoxy groups/amino groups), of 0.81.

### Example 8

A composition was prepared in the same manner as in Example 1 except that 5 parts by weight of 1,4-phenylenediamine in addition to 33 parts by weight of 3,3′-diethyl-4,4′-diaminodiphenylmethane was used. The composition obtained had a molar ratio, [epoxy groups/amino groups], of 0.71.

### Example 9

A composition was prepared in the same manner as in Example 1 except that 5 parts by weight of 3,3-diaminopropylamine in addition to 33 parts by weight of 3,3′-diethyl-4,4′-diaminodiphenylmethane was used. The composition obtained had a molar ratio, (epoxy groups/amino groups], of 0.75.

### Example 10

A composition was prepared in the same manner as in Example 1 except that 5 parts by weight of p-anisidine in addition to 33 parts by weight of 3,3′-diethyl-4,4′-diaminodiphenylmethane was used.

### Example 11

A composition was prepared in the same manner as in Example 1 except that 5 parts by weight of 2,6-diehylaniline in addition to 33 parts by weight of 3,3′-diethyl-4,4′-diaminodiphenylmethane was used.

### Referential Example 1

A composition was prepared in the same manner as in Example 1 except that 63.8 parts by weight of 3,3′-diethyl-4,4′-diaminodiphenylmethane was used. The composition obtained had a molar ratio, [epoxy groups/amino groups], of 0.5.

### Referential Example 2

A composition was prepared in the same manner as in Example 1 except that 5 parts by weight of octadecylamine in addition to 33 parts by weight of 3,3′-diethyl-4,4′-diaminodiphenylmethane was used.

### Referential Example 3

A composition was prepared in the same manner as in Example 1 except that 5 parts by weight of aniline in addition to 33 parts by weight of 3,3′-diethyl-4,4′-diaminodiphenylmethane was used.

### Referential Example 4

A composition was prepared in the same manner as in Example 1 except that 5 parts by weight of 1,6-diaminopyrene in addition to 33 parts by weight of 3,3′-diethyl-4,41-diaminodiphenylmethane was used. In the composition, 1,6-diaminopyrene was dispersed in the form of solid.

### Referential Example 5

A composition was prepared in the same manner as in Example 1 except that 5 parts by weight of 2-aminoethanol in addition to 33 parts by weight of 3,3′-diethyl-4,4′-diaminodiphenylmethane was used.

### Comparative Example 1

A composition was prepared in the same manner as in Example 1 except that 31.9 parts by weight of 3,3′-diethyl-4,4′-diaminodiphenylmethane was used. The composition obtained had a molar ratio, [epoxy groups/amino groups], of 1.0.

### Comparative Example 2

A composition was prepared in the same manner as in Example 1 except that 22.4 parts by weight of diethyltoluene was used. The composition obtained had a molar ratio, [epoxy groups/amino groups], of 1.0.

Table 1 shows properties of the amine curing agents and the amine compounds used.

TABLE 1

| | | | Melting | Boiling |
|---|---|---|---|---|
| Amine compound | State @25° C. | Amine equivalent | point, ° C. | point, ° C. |
| 3,3′-diethyl-4,4′-diaminodiphenylmethane | Liquid | 63.5 | — | 230/5 mmHg |
| diethyltoluenediamine | Liquid | 44.6 | — | 308 |
| 7,11-octadecadiene-1,18-dicarbohydrazide | Solid | 91.5 | 160 | 200< |
| 1,3-bis(hydrazinocarbonoethyl-5-isopropyl hydantoin | Solid | 78.5 | 120 | 200< |
| 4,4-diaminodiphenylmethane | Solid | 49.6 | 91 | 398 |
| 1,4-phenylenediamine | Solid | 27.0 | 142 | 267 |
| 3,3-diaminodipropylamine | Liquid | 32.8 | — | 235 |
| p-anisidine | Solid | 61.6 | 56 | 240 |
| 2,6-diethylaniline | Solid | 74.6 | — | 243 |
| octadecylamine | Solid | 134.8 | 50 | 232 |
| aniline | Liquid | 46.6 | — | 184 |
| 1,6-diaminopyrene | Solid | 58.1 | 230 | — |
| 2-aminoethanol | Liquid | 30.6 | — | 170 |

Each composition was evaluated according to the following methods.

(1) Viscosity

Using a BH type rotating viscometer, viscosity at 25° C. was measured at 4 rpm.

(2) Storage Stability

Each composition was kept in an atmosphere of 25° C. and a 60% RH for 48 hours. Potlife, i.e., a length of time a composition retains viscosity low enough to be processed, of each composition was rated according to the following criteria.

A: Long potlife with less than 30% change in viscosity from the initial viscosity

B: A little bit short potlife with 30 to 50% change in viscosity from the initial viscosity

C: Short potlife with more than 100% change in viscosity from the initial viscosity

Viscosity was measured in the same manner as described (1) above.

(3) Adhesion Strength

On a silicon chip coated with cured photosensitive polyimide resin, each composition was molded in the shape of a circular truncated cone with a top surface diameter of 2 mm, a basal surface diameter of 5 mm and a height of 5 mm, by heating at 120° C. for 0.5 hour and then 165° C. for 3 hours. Initial adhesion strength of the molded product to the silicone chip was measured by pushing the side surface of the molded product at 0.2 mm/sec. This test piece was then placed in a pressure cooker tester and kept in an atmosphere of 121° C. and 2.1 atm for 336 hours. After taking out the test piece from the pressure cooker tester, adhesion strength of the molded product to the silicon chip was measured in the aforesaid method. Total five test pieces were tested and the obtained data were averaged.

(4) Soldering Property

A flip-chip type semiconductor chip having four sections per chip with 576 Sn3.0/Ag0.5/Cu solder bumps per section and a substrate were used. Each composition was applied on the substrate with a dispenser, on which the semiconductor chip was mounted with a flip-chip bonder at a soldering temperature of 260° C. for 3 seconds with 10N load. Then, the applied composition was cured at 120° C. for 0.5 hour and then 165° C. for 3 hours. Electrical connection of the semiconductor test piece thus obtained was examined. Total 10 test pieces, i.e., total 40 sections, were prepared for each composition and the number of sections was counted in which electrical connection via solder was confirmed.

(5) Void

The test pieces prepared in the above test were observed with a supersonic flow detector for voids. The number of chips in which a void was found were counted.

(6) Exfoliation

Among the test pieces prepared for the soldering property test, total 10 semiconductor chips without a void were kept in an atmosphere of 30° C. and 65% RH for 192 hours. Then, the test pieces were passed in an IR reflow furnace with a peak temperature of 265° C. for five times and then observed for cracks or exfoliation with the super sonic flow detector. The number of chips without cracks and exfoliation was counted. Subsequently, the test pieces were kept in an atmosphere of 121° C. at 2.1 atm in a pressure cooker tester for 336 hours and observed for cracks or exfoliation with the super sonic flow detector. The number of chips without a crack and exfoliation was counted.

(7) Temperature Cycle Test

Among the test pieces prepared in the soldering property test, total 10 semiconductor chips without a void were kept in an atmosphere of 30° C. and 65% RH for 192 hours and then subjected to a heat cycle test in which one cycle consisted of cooling at −65° C. for 30 minutes and then heating at 150° C. for 30 minutes, for 250, 500, 750 and 1000 cycles. The chips were observed for cracks or exfoliation and the number of chips without a crack and exfoliation was counted.

The results are as shown in Tables 2 and 3.

TABLE 2

| | | Example | | | | | | | | | | |
|---|---|---|---|---|---|---|---|---|---|---|---|---|
| | | 1 | 2 | 3 | 4 | 5 | 6 | 7 | 8 | 9 | 10 | 11 |
| Viscosity(Pa · s, 25° C.) | | 38 | 45 | 41 | 32 | 69 | 68 | 66 | 65 | 41 | 65 | 38 |
| Sorage stability | | A | A | A | A | A | A | A | A | A | A | A |
| Adhesion strength | Initial | 1170 | 1350 | 1240 | 1170 | 1400 | 1280 | 1360 | 1370 | 1340 | 1380 | 1270 |
| (MPa) | PCT 336 hr | 1040 | 1240 | 1150 | 1050 | 1280 | 1180 | 1250 | 1230 | 1250 | 1240 | 1180 |
| Soldering properety | | 40/40 | 36/40 | 39/40 | 38/40 | 39/40 | 40/40 | 36/40 | 37/40 | 38/40 | 36/40 | 35/40 |
| Void | | 0/10 | 0/10 | 0/10 | 0/10 | 0/10 | 0/10 | 0/10 | 0/10 | 0/10 | 0/10 | 0/10 |
| Exfoliation | IR furnace | 0/10 | 0/10 | 0/10 | 0/10 | 0/10 | 0/10 | 0/10 | 0/10 | 0/10 | 0/10 | 0/10 |
| | 5 passes | | | | | | | | | | | |
| | PCT 336 hr | 0/10 | 0/10 | 0/10 | 0/10 | 0/10 | 0/10 | 0/10 | 0/10 | 0/10 | 0/10 | 0/10 |
| Temperature | 250 cycles | 0/10 | 0/10 | 0/10 | 0/10 | 0/10 | 0/10 | 0/10 | 0/10 | 0/10 | 0/10 | 0/10 |
| cycle | 500 cycles | 0/10 | 0/10 | 0/10 | 0/10 | 0/10 | 0/10 | 0/10 | 0/10 | 0/10 | 0/10 | 0/10 |
| | 750 cycles | 0/10 | 0/10 | 0/10 | 0/10 | 0/10 | 0/10 | 0/10 | 0/10 | 0/10 | 0/10 | 0/10 |
| | 1000 cycles | 0/10 | 0/10 | 0/10 | 0/10 | 0/10 | 0/10 | 0/10 | 0/10 | 0/10 | 0/10 | 0/10 |

TABLE 3

| | | | | | | | Comparative | |
|---|---|---|---|---|---|---|---|---|
| | | Referential example | | | | | example | |
| | | 1 | 2 | 3 | 4 | 5 | 1 | 2 |
| Viscosity(Pa · s, 25° C.) | | 28 | 68 | 42 | 67 | 38 | 50 | 39 |
| Sorage stability | | A | A | B | A | C | A | A |
| Adhesion strength | Initial | 690 | 890 | 1120 | 1230 | 1280 | 1450 | 1210 |
| (MPa) | PCT 336 hr | 150 | 450 | 680 | 1050 | 1120 | 1300 | 1060 |
| Soldering properety | | 38/40 | 0/40 | 0/40 | 0/40 | 0/40 | 20/40 | 26/40 |
| Void | | 1/10 | 0/10 | 10/10 | 0/10 | 10/10 | 0/10 | 0/10 |
| Exfoliation | IR furnace | 8/10 | 8/10 | | 3/10 | | 0/10 | 0/10 |
| | 5 passes | | | | | | | |
| | PCT 336 hr | 10/10 | 10/10 | | 6/10 | | 0/10 | 0/10 |
| Temperature cycle | 250 cycles | 10/10 | 10/10 | | 0/10 | | 0/10 | 0/10 |
| | 500 cycles | | | | 3/10 | | 0/10 | 0/10 |
| | 750 cycles | | | | 10/10 | | 0/10 | 0/10 |
| | 1000 cycles | | | | | | 0/10 | 0/10 |

As shown in Tables 2 and 3, the epoxy resin composition of Examples had good storage stability, adhesion strength, and soldering properties to give cured products with no void.

The compositions of Comparative Examples 1 and 2, each comprising equimolar amounts of the epoxy resin and the curing agent, showed insufficient flux property.

The composition of Reference Example 1 contained excess amount of the curing agent and gave a cured product having low adhesion strength.

The amine compound used in Reference Examples 2 has a relative large amine equivalent, so that 5 parts by weight thereof was not enough content to attain sufficient flux effect.

The amine compounds used in Reference Examples 3 and 5 have low boiling points to cause voids in cured products.

The monoamine compound used in Referential Examples 4 has a high melting point and was not so miscible in the composition, causing exfoliation.

1. A liquid epoxy resin composition comprising
(A) a liquid epoxy resin
(B) an amine curing agent and
(C) an inorganic filler in an amount of from 50 to 900 parts by weight per 100 parts by weight of the component (A), wherein the component (B) is contained in such an amount that a molar ratio of epoxy groups of the component (A) to amino groups of the component (B), ranges from 0.6 to less than 1.0, provided that, if the component (B) includes an amine curing agent which is solid in the composition at a temperature of from room temperature to 150° C., a content of such an amine is 30 mol % or less, based on the component (B).

2. The liquid epoxy resin composition according to claim 1, wherein the molar ratio ranges from 0.6 to less than 0.8.

3. The liquid epoxy resin composition according to claim 1, wherein the content of the amine curing agent which is solid in the composition at a temperature of from room temperature to 150° C. is 20 mol % or less, based on the component (B).

4. A liquid epoxy resin composition comprising
(A) a liquid epoxy resin
(B) an amine curing agent and
(C) an inorganic filler in an amount of from 50 to 900 parts by weight per 100 parts by weight of the component (A), wherein the component (B) is contained in such an amount that a molar ratio of epoxy groups of the component (A) to amino groups of the component (B) ranges from 0.8 to less than 1.1, and the composition further comprises
(D) a monoamine compound having a melting point of 200° C. or lower and a boiling point of 200° C. or higher in an amount of from 0.1 to 20 parts by weight per total 100 parts by weight of the components (A) and (B).

5. The liquid epoxy resin composition according to claim 4, wherein the monoamine compound (D) is an aniline derivative.

6. The liquid epoxy resin composition according to claim 5, wherein the aniline derivative is selected from the group consisting of p-anisidine and 2,6-diethylaniline.

7. The liquid epoxy composition according to claim 1 or 4, wherein the component (B) comprises an aromatic amine.

8. The liquid epoxy composition according to claim 7, wherein the aromatic amine is selected from the group consisting of 1,2-phenylenediamine, 1,3-phenylenediamine, and 1,4-phenylenediamine.

9. The liquid epoxy composition according to claim 1 or 4, wherein the amine curing agent (B) is selected from the group consisting of 1,3-bis(hydrazinocarbonoethyl-5-isopropyl hydantoin and 7,11-octadecadiene-1,18-dicarbohydrazide.

10. The composition according to claim 1 or 4, wherein the composition further comprises (E) a silicone-modified epoxy resin represented by the following formula (6) in an amount of 20 parts by weight or less per 100 parts by weight of the component (A) 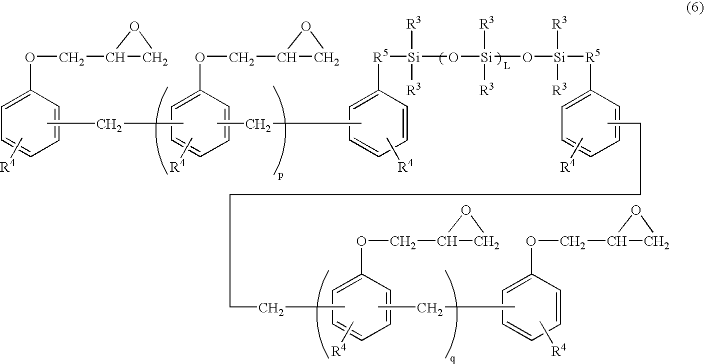
wherein R⁴ is a hydrogen atom or a monovalent hydrocarbon group having 1 to 6 carbon atoms, R⁵ is a divalent group represented by the formula, —CH₂CH₂CH₂—, —OCH₂—CH(OH)—CH₂—O—CH₂CH₂CH₂—, or —O—CH₂CH₂CH₂—, L is an integer of from 8 to 398, p is an integer of from 1 to 10, and q is an integer of from 1 to 10.

11. The composition according to claim 1 or 4, wherein the composition is for encapsulating a flip-chip type semiconductor.

12. A flip-chip type semiconductor device comprising a cured product of the composition according to claim 11.
